(19) United States
(12) Patent Application Publication
(10) Pub. No.: US 2026/0280557 A1
(43) Pub. Date: Sep. 17, 2026

(54) DRIVING APPARATUS AND DRIVING METHOD FOR GALLIUM NITRIDE DEVICE

(71) Applicant: Lucid Microsystems Co., Ltd., Suwon-si (KR)

(72) Inventors: Young Min LEE, Seoul (KR); Ki Sun LEE; Kyung Hoon SONG, Suwon-si (KR)

(73) Assignee: Lucid Microsystems Co., Ltd., Suwon-si, GG (KR)

(21) Appl. No.: 19/166,100

(22) PCT Filed: Mar. 21, 2024
(86) PCT No.: PCT/KR2024/003549

§ 371 Date: Sep. 17, 2025

(30) Foreign Application Priority Data
Mar. 21, 2023 (KR) 10-2023-0036648
Mar. 21, 2024 (KR) 10-2024-0038822

(51) Int. Cl. H03K 17/687

(52) U.S. Cl. CPC H03K 17/687

(57) ABSTRACT

Driving apparatus for a gallium nitride (GaN) device are disclosed. The driving apparatus has a gate driver for supplying a gate terminal of a GaN device with a driving voltage generated by using a reference voltage and a driving high voltage; and a voltage selector for applying, as the reference voltage of the gate driver, a lower one between voltages at a first drain terminal and a second drain terminal of the GaN device.

### TECHNICAL FIELD

This embodiment relates to the driving of a GaN (Gallium Nitride) device.

### BACKGROUND ART

In recent years, the importance of a bi-directional voltage blocking function is increasing in various fields including power processing devices. A bi-directional converter performs a key role in various systems such as battery charge and discharge management, regenerative braking of electric vehicles, and grid-connected energy storage. Since these systems allow power to flow in both directions, the provision of the bi-directional voltage blocking function may be essential.

In addition to the bi-directional converter, this function is also considered to be important in other power processing devices, such as inverters connected to renewable energy sources. These systems are required to efficiently manage power flow from a power source (e.g., a photovoltaic panel or a wind turbine) to a grid or from the grid to the power source, whereby the application of the bi-directional voltage blocking function is being expanded.

In order to implement the bi-directional voltage blocking function in the power processing device, a Si-MOSFET (Silicon Metal-Oxide-Semiconductor Field-Effect Transistor) device has traditionally been widely used. However, since a parasitic diode exists in the Si-MOSFET, at least two or more Si-MOSFET devices were required to implement the bi-directional voltage blocking function. However, this has the drawback of increasing the size of the system, raising material costs, and increasing power loss due to high impedance between power input and output.

### DETAILED DESCRIPTION

### Technical Problem

In one aspect, an objective of this embodiment is to provide a bi-directional voltage blocking technology that can reduce the size of a system and lower material costs. In another aspect, an objective of this embodiment is to provide a technology for implementing a bi-directional voltage blocking function using a GaN device in which a parasitic diode is not formed. In a further aspect, an objective of this embodiment is to provide a technology for a driving method for a GaN device that can minimize power loss in the GaN device.

### Technical Solution

In order to accomplish the above-described objectives, one embodiment provides a driving apparatus for a gallium nitride (GaN) device, the driving apparatus including a gate driver for supplying a gate terminal of the GaN device with a driving voltage generated by using a reference voltage and a driving high voltage; and a voltage selector for applying, as the reference voltage of the gate driver, a lower one between voltages at a first drain terminal and a second drain terminal of the GaN device.

The gate driver may be supplied with driving power through a charge pump, and the reference voltage may be used as a low voltage of the charge pump.

The voltage selector may include a first switch disposed between the first drain terminal and the gate driver and a second switch disposed between the second drain terminal and the gate driver, and may turn on one of the first switch and the second switch to apply the lower one between the voltages as the reference voltage of the gate driver.

The first switch and the second switch each may include a parasitic diode formed between a drain and a source.

An anode electrode of the parasitic diode may be connected to a reference terminal of the gate driver, and a cathode electrode of the parasitic diode may be connected to the first drain terminal or the second drain terminal.

A forward voltage of the parasitic diode may be lower than a threshold voltage of a gate-drain of the GaN device.

Another embodiment provides a driving method for a gallium nitride (GaN) device, the driving method including applying a lower one between voltages at a first drain terminal and a second drain terminal of the GaN device, as a reference voltage of a gate driver; and supplying a turn-off driving voltage having a voltage level corresponding to the reference voltage to a gate terminal of the GaN device, thereby making impedance between the first drain terminal and the second drain terminal of the GaN device high impedance (Hi-Z).

In the applying the lower voltage as the reference voltage of the gate driver, the drain terminal having a lower voltage between the first drain terminal and the second drain terminal may be connected to the reference terminal of the gate driver.

A first switch may be disposed between the first drain terminal and the reference terminal, a second switch may be disposed between the second drain terminal and the reference terminal, and one of the first switch and the second switch may be turned on to connect the drain terminal having a lower voltage to the reference terminal.

The gate driver may be supplied with driving power through a charge pump, and the first switch and the second switch each may include a parasitic diode formed between a drain and a source.

A further embodiment provides a driving method for a gallium nitride (GaN) device, the driving method including obtaining a voltage of a first drain terminal, in which an average voltage in the GaN device is formed lower than that of a second drain terminal; and supplying, to a gate terminal of the GaN device, a turn-off driving voltage that is higher than the voltage of the first drain terminal and lower than a voltage obtained by adding a threshold voltage of the GaN device to the voltage of the first drain terminal.

When the turn-off driving voltage is supplied to the gate terminal, current of an inductor connected to the GaN device may flow from the first drain terminal to the second drain terminal.

The turn-off driving voltage may be supplied through a gate driver to the gate terminal of the GaN device, and the voltage of the first drain terminal may be used as a reference voltage of the gate driver.

The gate driver may be supplied with driving power through a charge pump, and the reference voltage may be commonly used by the gate driver and the charge pump.

A switch may be disposed between the first drain terminal and the gate driver, the switch may include a parasitic diode therein, an anode electrode of the parasitic diode may be connected to the gate driver, and a cathode electrode of the parasitic diode may be connected to the first drain terminal.

### Effects of Invention

As described above, in accordance with this embodiment, it is possible to provide a bi-directional voltage blocking technology that can reduce the size of a system and lower material costs. Further, in accordance with this embodiment, it is possible to implement a bi-directional voltage blocking function using a GaN device in which a parasitic diode is not formed. Further, in accordance with this embodiment, it is possible to drive a GaN device while minimizing power loss in the GaN device.

### BRIEF DESCRIPTION OF DRAWINGS

FIG. 1 is a configuration diagram illustrating a circuit in which Si-MOSFETs are connected back-to-back with a common drain to block voltage in both directions.

FIG. 2 is a configuration diagram illustrating a circuit in which Si-MOSFETs are connected back-to-back with a common source to block voltage in both directions.

FIG. 3 is a configuration diagram of a bi-directional voltage blocking circuit according to one embodiment.

FIG. 4 is a diagram illustrating the configuration of a voltage selector according to one embodiment.

FIG. 5 is a diagram illustrating that a gate driver is supplied with driving power from a charge pump according to one embodiment.

FIG. 6 is a flowchart of a method for driving a GaN device according to one embodiment.

FIG. 7 is a diagram for explaining power loss when a negative current flows through the GaN device.

FIG. 8 is a diagram illustrating a driving apparatus that reduces power loss of the GaN device according to one embodiment.

FIG. 9 is a diagram showing a driving voltage waveform of the driving apparatus according to the example of FIG. 8.

FIG. 10 is a configuration diagram of a bi-directional voltage blocking circuit to which the driving apparatus of FIG. 8 is applied.

FIG. 11 is a flowchart of a driving method for the driving apparatus shown in FIG. 10.

### BEST MODE FOR CARRYING OUT THE INVENTION

Hereinafter, some embodiments of the present disclosure will be described in detail with reference to exemplary drawings. When adding reference numerals to components of each drawing, it should be noted that the same numerals are given to the same components even if they are shown in different drawings. Further, in describing the present disclosure, when it is determined that a detailed description of related well-known configurations or functions may obscure the gist of the present disclosure, a detailed description thereof will be omitted.

Furthermore, in describing the components of the present disclosure, terms such as first, second, A, B, (a), (b), and the like may be used. Such terms are merely for distinguishing one component from another component, and the nature, order, or sequence of the component is not limited by these terms. When a certain component is described as being “connected,” “coupled,” or “linked” to another component, it should be understood that the component may be directly connected or linked to the other component, but another component may also be “connected,” “coupled,” or “linked” between the respective components.

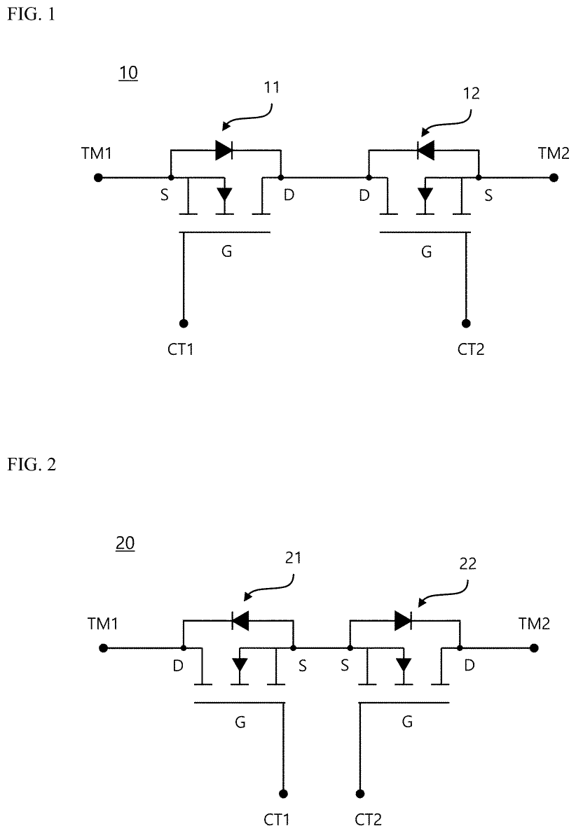

FIG. 1 is a configuration diagram illustrating a circuit in which Si-MOSFETs are connected back-to-back with a common drain to block voltage in both directions.

Referring to FIG. 1, a bi-directional voltage blocking circuit 10 may include a first MOSFET 11 and a second MOSFET 12. A source terminal S of the first MOSFET 11 may be connected to a first terminal TM1, and a source terminal S of the second MOSFET 12 may be connected to a second terminal TM2. Further, drain terminals D of the first MOSFET 11 and the second MOSFET 12 may be commonly connected to each other. Further, control signals CT1 and CT2 may be supplied to gate terminals G of the first MOSFET 11 and the second MOSFET 12, respectively.

Parasitic diodes may be formed in the MOSFETs 11 and 12, and depending on the arrangement of anode and cathode electrodes of each parasitic diode, the parasitic diode of the first MOSFET 11 may block power flowing from the second terminal TM2 to the first terminal TM1, and the parasitic diode of the second MOSFET 12 may block power flowing from the first terminal TM1 to the second terminal TM2.

Since the bi-directional voltage blocking circuit 10 includes two MOSFETs 11 and 12, there is a problem in that the size of a system is large. In addition, there may be difficulty in control because the control signals CT1 and CT2 should be supplied to the first MOSFET 11 and the second MOSFET 12, respectively, from a control perspective.

FIG. 2 is a configuration diagram illustrating a circuit in which Si-MOSFETs are connected back-to-back with a common source to block voltage in both directions.

Referring to FIG. 2, a bi-directional voltage blocking circuit 20 may include a first MOSFET 21 and a second MOSFET 22. A drain terminal D of the first MOSFET 21 may be connected to the first terminal TM1, and a drain terminal D of the second MOSFET 22 may be connected to the second terminal TM2. Further, source terminals S of the first MOSFET 21 and the second MOSFET 22 may be commonly connected to each other. Further, control signals CT1 and CT2 may be supplied to gate terminals G of the first MOSFET 21 and the second MOSFET 22, respectively.

Parasitic diodes may be formed in the MOSFETs 21 and 22, and depending on the arrangement of anode and cathode electrodes of each parasitic diode, the parasitic diode of the first MOSFET 21 may block power flowing from the first terminal TM1 to the second terminal TM2, and the parasitic diode of the second MOSFET 22 may block power flowing from the second terminal TM2 to the first terminal TM1.

Since the bi-directional voltage blocking circuit 20 includes two MOSFETs 21 and 22, there is a problem in that the size of a system is large. In addition, there may be difficulty in control because the control signals CT1 and CT2 should be supplied to the first MOSFET 21 and the second MOSFET 22, respectively, from a control perspective.

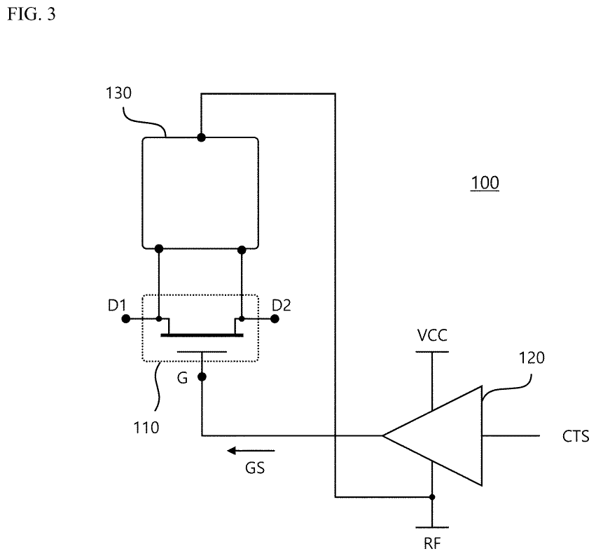

FIG. 3 is a configuration diagram of a bi-directional voltage blocking circuit according to one embodiment.

Referring to FIG. 3, the bi-directional voltage blocking circuit 100 may include a GaN device 110, a gate driver 120, a voltage selector 130, etc. Here, the gate driver 120 and the voltage selector 130 may be a driving apparatus for the GaN device 110.

GaN (Gallium Nitride) is a compound composed of nitrogen (N) and gallium (Ga), and is used as a semiconductor material. The GaN device 110 is also referred to as a GaN power semiconductor and is used in a power electronics field to replace or complement existing silicon (Si)-based semiconductors.

The GaN device 110 is known to have a higher electron mobility compared to the silicon-based semiconductors. Thus, the GaN device 110 may exhibit relatively lower power loss and higher efficiency. GaN may have a higher critical electric field strength than silicon. As a result, the GaN device 110 may withstand a high voltage in a thinner layer, thereby reducing the size of the device and improving its performance. In addition, the GaN device 110 can effectively operate at high frequencies, remains stable even in high-temperature environments, has low on-resistance, and is fast in switching speed, thereby offering high energy efficiency.

Meanwhile, the GaN device 110 may not include a parasitic diode as shown in FIG. 3. In the following description, a driving method for the GaN device 110 that does not include the parasitic diode will be described.

A first drain terminal D1, a second drain terminal D2, and a gate terminal G may be formed in the GaN device 110. Current may flow from the first drain terminal D1 to the second drain terminal D2 or from the second drain terminal D2 to the first drain terminal D1.

In the GaN device 110, when a gate-first drain voltage, which is the voltage between the gate G and the first drain D1, is higher than a threshold voltage Vth, or when a gate-second drain voltage, which is the voltage between the gate G and the second drain D2, is higher than the threshold voltage Vth, the GaN device 110 may be turned on. As one example, when the threshold voltage Vth is 1V, the GaN device 110 may be turned on if the gate-first drain voltage is greater than 1V. As another example, when the threshold voltage Vth is 1V, the GaN device 110 may be turned on if the gate-second drain voltage is greater than 1V.

When both the gate-first drain voltage and the gate-second drain voltage in the GaN device 110 are lower than the threshold voltage Vth, the GaN device 110 may be turned off. Since no parasitic diode is formed in the GaN device 110 when the GaN device 110 is turned off, impedance between the first drain terminal D1 and the second drain terminal D2 of the GaN device 110 may become high impedance Hi-Z. Here, the high impedance Hi-Z may vary depending on an application to which the GaN device 110 is applied or the size of the GaN device 110, but may be an impedance value of approximately 1 MΩ or more. In this way, a state in which the impedance between the first drain terminal D1 and the second drain terminal D2 becomes the high impedance Hi-Z may be said to be a state in which the bi-directional voltage is blocked.

In order for the GaN device 110 to be a state of blocking the bi-directional voltage, both the gate-first drain voltage and the gate-second drain voltage should be lower than the threshold voltage Vth. To this end, one embodiment may check the first drain voltage and the second drain voltage. Further, one embodiment may determine the gate voltage using a lower one between the voltages at the first drain terminal and the second drain terminal. For example, when the first drain voltage is lower than the second drain voltage, and the gate-first drain voltage becomes lower than the threshold voltage Vth through the control of the gate voltage, the gate-second drain voltage also becomes lower than the threshold voltage Vth.

The gate driver 120 may supply a driving voltage GS to the gate terminal G of the GaN device 110. At this time, the gate driver 120 may receive the lower one between the voltages at the first drain terminal D1 and the second drain terminal D2 as a reference voltage RF. The gate driver 120 may generate, as a turn-off driving voltage, a driving voltage GS having a voltage level equal to the reference voltage RF or lower than a voltage obtained by adding a predetermined voltage, for example, the threshold voltage Vth, to the reference voltage RF, and then supply the turn-off driving voltage to the gate terminal G. When this turn-off driving voltage is supplied, the GaN device 110 may be turned off. On the other hand, the gate driver 120 may generate, as a turn-on driving voltage, a driving voltage GS having a voltage level higher than a voltage obtained by adding a predetermined voltage, for example, the threshold voltage Vth, to the reference voltage RF, and then supply the turn-off driving voltage to the gate terminal G. When this turn-on driving voltage is supplied, the GaN device 110 may be turned on.

The gate driver 120 may include an amplifier. Further, the amplifier may generate a driving voltage GS using a driving high voltage VCC and the reference voltage RF in response to a control input signal CTS. As one example, when the control input signal CTS is at a low voltage level, the amplifier may select and amplify the reference voltage RF supplied to the reference terminal of the amplifier and output it as the driving voltage GS. As another example, when the control input signal CTS is at a high voltage level, the amplifier may select and amplify the driving high voltage VCC supplied to the driving high voltage terminal of the amplifier and output it as the driving voltage GS.

In order to ensure that the driving voltage GS supplied to the gate terminal G does not fluctuate significantly with respect to the first drain terminal D1 or the second drain terminal D2 and has a relatively stable voltage level, and that the gate-first drain voltage or the gate-second drain voltage required for driving stably has a predetermined voltage level, for example, a turn-off driving voltage level or a turn-on driving voltage level, the gate driver 120 may receive a lower one between the voltages at the first drain terminal D1 and the second drain terminal D2, as the reference voltage RF.

The voltage selector 130 may select a lower one between the voltages at the first drain terminal D1 and the second drain terminal D2, and apply it as the reference voltage RF of the gate driver 120.

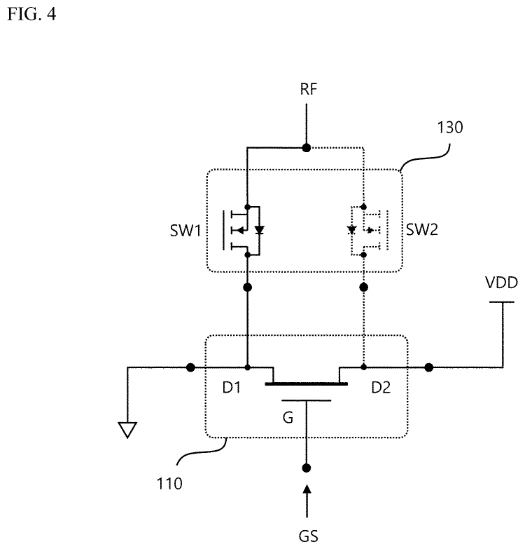

FIG. 4 is a diagram illustrating the configuration of a voltage selector according to one embodiment.

Referring to FIG. 4, the voltage selector 130 may include a first switch SW1 disposed between the first drain terminal D1 and the reference terminal of the gate driver, and a second switch SW2 disposed between the second drain terminal D2 and the reference terminal of the gate driver.

The voltage selector 130 may turn on one of the first switch SW1 and the second switch SW2 and apply a lower one between the voltages at the first drain terminal D1 and the second drain terminal D2 as the reference voltage RF of the gate driver. As one example, when the voltage of the first drain terminal D1 is lower than the voltage of the second drain terminal D2, the voltage selector 130 may turn on the first switch SW1 and turn off the second switch SW2 so that the voltage of the first drain terminal D1 is applied as the reference voltage RF. As another example, when the voltage of the second drain terminal D2 is lower than the voltage of the first drain terminal D1, the voltage selector 130 may turn on the second switch SW2 and turn off the first switch SW1 so that the voltage of the second drain terminal D2 is applied as the reference voltage RF.

When the GaN device 110 is turned on, the voltage of the first drain terminal D1 and the voltage of the second drain terminal D2 may become substantially equal. Therefore, the voltage selector 130 may apply, as the reference voltage RF, the voltage of the terminal having a lower average voltage level during a predetermined period of time, for example, a switching cycle.

In the example of FIG. 4, a ground voltage is supplied to the first drain terminal D1, and a high voltage VDD is supplied to the second drain terminal D2. In this connection state, since the average voltage of the first drain terminal D1 is lower than the average voltage of the second drain terminal D2, the voltage selector 130 may turn on the first switch SW1 and turn off the second switch SW2 to connect the first drain terminal D1 to the reference terminal of the gate driver.

The first switch SW1 and the second switch SW2 each may be a power semiconductor having a parasitic diode. For example, the first switch SW1 and the second switch SW2 each may be a MOSFET. The first switch SW1 and the second switch SW2 each may include a parasitic diode formed between a drain and a source.

The anode electrode of the parasitic diode embedded in each of the first switch SW1 and the second switch SW2 may be connected to the reference terminal of the gate driver, while the cathode electrode of the parasitic diode may be connected to the first drain terminal D1 or the second drain terminal D2. As one example, the anode electrode of the parasitic diode embedded in the first switch SW1 may be connected to the reference terminal of the gate driver, and the cathode electrode may be connected to the first drain terminal D1. As another example, the anode electrode of the parasitic diode embedded in the second switch SW2 may be connected to the reference terminal of the gate driver, and the cathode electrode may be connected to the second drain terminal D2.

A forward voltage Vf of the parasitic diode embedded in each of the first switch SW1 and the second switch SW2 may be lower than a gate-drain threshold voltage Vth of the GaN device 110. For example, the forward voltage Vf of the parasitic diode embedded in each of the first switch SW1 and the second switch SW2 may be 0.5V, while the gate-drain threshold voltage Vth of the GaN device 110 may be 1V.

Suppose that the first switch SW1 and the second switch SW2 are not operating properly for some reason. In this case, both the first switch SW1 and the second switch SW2 may be turned off. Under such a circumstance, the gate driver may supply the reference voltage RF as the driving voltage GS to provide a bi-directional voltage blocking function.

If the reference voltage RF has a voltage level higher than the voltage of the first drain terminal D1—substantially by more than the forward voltage Vf—the parasitic diode of the first switch SW1 may conduct and the voltage of the first drain terminal D1 may be applied as the reference voltage RF. In practice, a voltage corresponding to the voltage of the first drain terminal D1+the forward voltage Vf may be formed as the reference voltage RF.

If the reference voltage RF has a voltage level higher than the voltage of the second drain terminal D2—substantially by more than the forward voltage Vf—the parasitic diode of the second switch SW2 may conduct and the voltage of the second drain terminal D2 may be applied as the reference voltage RF. In practice, a voltage corresponding to the voltage of the second drain terminal D2+the forward voltage Vf may be formed as the reference voltage RF.

At this time, the voltage supplied to the gate terminal G of the GaN device 110 is the voltage of the first drain terminal D1+the forward voltage Vf or the voltage of the second drain terminal D2+the forward voltage Vf. Since this voltage is lower than the voltage of the first drain terminal D1+the threshold voltage Vth or the voltage of the second drain terminal D2−the threshold voltage Vth, the GaN device 110 can maintain the turn-off state while performing the bi-directional voltage blocking function.

As such, applying, by the voltage selector 130, the lower one between the voltages at the first drain terminal and the second drain terminal as the reference voltage of the gate driver may be more frequently used when the gate driver has a floating voltage supply source, such as a charge pump.

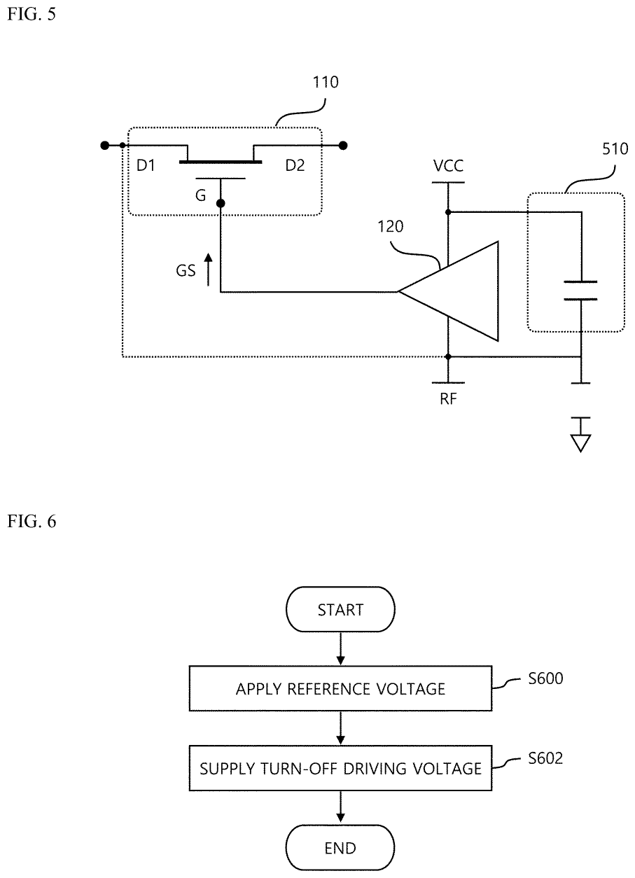

FIG. 5 is a diagram illustrating that a gate driver is supplied with driving power from a charge pump according to one embodiment.

Referring to FIG. 5, the gate driver 120 may receive driving power from the charge pump 510. The charge pump 510 may apply a low voltage and a high voltage to the gate driver 120. At this time, the low voltage may be the same as the reference voltage of the gate driver 120, and the high voltage may become the driving high voltage VCC of the gate driver 120.

The first drain terminal D1 or the second drain terminal D2 of the GaN device 110 may be in a floating state without being connected to the ground, and the charge pump 510 capable of floating the low voltage may be used to supply driving power to the GaN device 110 in the floating state.

The low voltage of the charge pump 510 may float without being connected to the ground. At this time, if a reference for the low voltage is not properly provided, a voltage difference between the driving voltage GS supplied to the gate terminal G and the first drain terminal D1 or the second drain terminal D2 may become unstable, so that the GaN device 110 may be destroyed. Thus, the reference voltage RF of the gate driver 120 may be used as the low voltage of the charge pump 510.

FIG. 6 is a flowchart of a method for driving a GaN device according to one embodiment.

Referring to FIG. 6, the driving apparatus may apply a lower one between the voltages at the first drain terminal and the second drain terminal of the GaN device as the reference voltage of the gate driver, in step S600.

The driving apparatus may apply the voltage of the terminal with a lower average voltage among the first drain terminal and the second drain terminal as the reference voltage of the gate driver. For example, the driving apparatus may use a switch to connect the drain terminal having a lower voltage level among the first drain terminal and the second drain terminal to the reference terminal of the gate driver.

A first switch may be disposed between the first drain terminal and the reference terminal, and a second switch may be disposed between the second drain terminal and the reference terminal. Further, the driving apparatus may turn on either of the first switch or the second switch to connect the drain terminal having a lower voltage level among the drain terminals and the reference terminal of the gate driver.

The gate driver may be supplied with the driving power through the charge pump, and the first switch and the second switch each may include the parasitic diode formed between the drain and the source. Further, the gate driver may control not only the GaN device but also the turn-on/turn-off of the first switch and the second switch. However, in this structure, the gate driver may fail to normally turn on the first switch and the second switch, due to the abnormality of the gate driver and/or the charge pump. In this case, through the parasitic diodes formed in the first switch and the second switch, the lower one between the voltages at the first drain terminal and the second drain terminal may be applied as the reference voltage of the gate driver. By this operation, the gate driver may smoothly perform the bi-directional voltage blocking function using the GaN device.

After controlling the reference voltage of the gate driver, the driving apparatus may supply a turn-off driving voltage having a voltage level corresponding to the reference voltage to the gate terminal of the GaN device, thereby setting the impedance between the first drain terminal and the second drain terminal of the GaN device to a high impedance Hi-Z.

Meanwhile, when the GaN device is used in a power conversion circuit including an inductor, power loss may occur as a negative current Ine flows between the drain terminals D1 and D2 even in a state where the turn-off driving voltage is supplied to the GaN device.

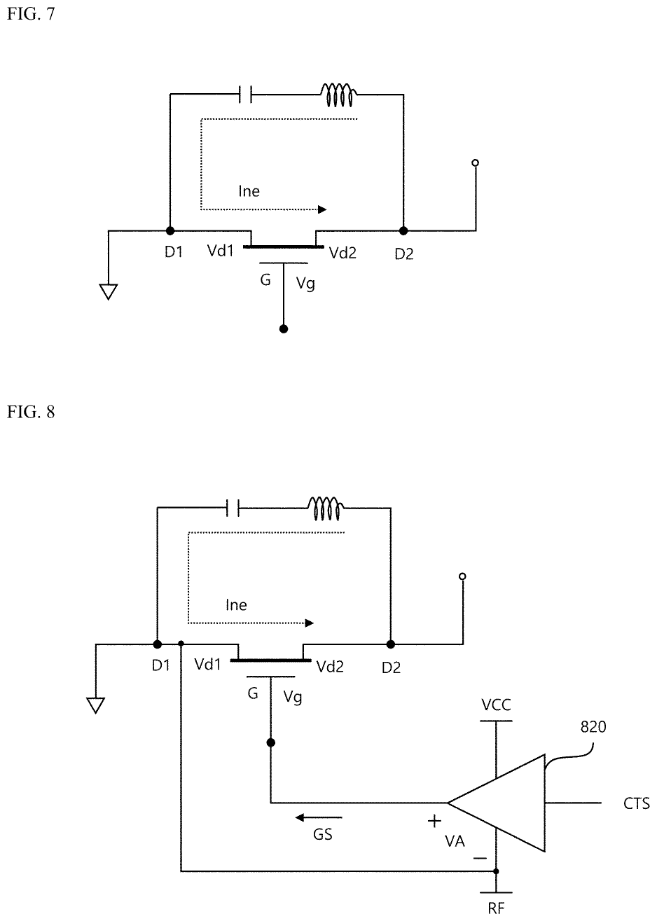

FIG. 7 is a diagram for explaining power loss when a negative current flows through the GaN device.

The gate driver may supply the reference voltage as the turn-off driving voltage. Further, this reference voltage may be equal to the voltage Vd1 of the first drain terminal with a low average voltage. Vg=Vd1.

Since the negative current Ine flows from the first drain terminal D1 to the second drain terminal D2, the first drain terminal voltage Vd1 may be higher than the second drain terminal voltage Vd2. Vd1>Vd2.

The condition under which the negative current Ine flows is when a difference between the gate voltage Vg and the second drain terminal voltage Vd2 is equal to or greater than the threshold voltage Vth. Vg−Vd2=Vth+DV. Here, DV is used to indicate that the difference between the gate voltage Vg and the second drain terminal voltage Vd2 is higher than the threshold voltage Vth by an arbitrary voltage DV.

In summary, since Vg−Vd2=Vth+DV and Vg=Vd1, it follows that Vd1−Vd2=Vth+DV. Further, the power loss between the first drain terminal D1 and the second drain terminal D2 is given by: power loss=Ine*(Vth+DV).

FIG. 8 is a diagram illustrating a driving apparatus that reduces power loss of the GaN device according to one embodiment.

Referring to FIG. 8, the gate driver 820 may generate driving voltage GS using the reference voltage RF and the driving high voltage VCC, and may supply the driving voltage GS to the gate terminal G of the GaN device.

The gate driver 820 may obtain the voltage Vd1 of the first drain terminal D1, in which the average voltage of the GaN device is formed lower than that of the second drain terminal D2. Further, the gate driver 820 may use the voltage Vd1 of the first drain terminal as the reference voltage RF.

When generating the turn-off driving voltage, the gate driver 820 may supply the turn-off driving voltage, which is higher than the first drain terminal voltage Vd1 and is lower than the voltage Vd1+Vth obtained by adding the threshold voltage Vth of the GaN device to the first drain terminal voltage Vd1, to the gate terminal G of the GaN device.

For example, the gate driver 820 may generate a turn-off driving voltage that is higher than the reference voltage RF by the VA voltage, and supply this turn-off driving voltage to the gate terminal G. Here, VA may be a voltage that satisfies the relation 0<VA<Vth.

When such a turn-off driving voltage is supplied to the gate terminal G, Vg=Vd1+VA may be obtained. Since Vg−Vd2=Vth+DV, the relation Vd1−Vd2=Vth+DV−VA may be established. Further, the power loss in the GaN device may be expressed as Ine*(Vth+DV−VA).

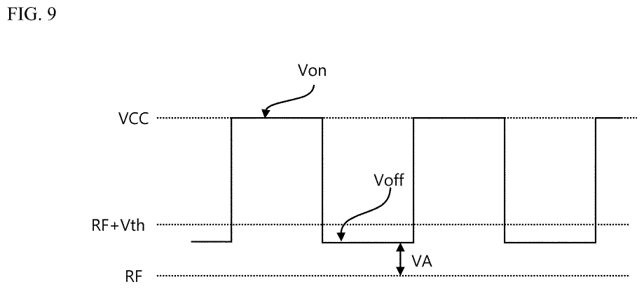

FIG. 9 is a diagram showing a driving voltage waveform of the driving apparatus according to the example of FIG. 8.

Referring to FIG. 9, the turn-off driving voltage Voff may be formed to be higher than the reference voltage RF and lower than the reference voltage RF+threshold voltage Vth. The gate driver may generate a turn-off driving voltage having an offset equal to the VA voltage from the reference voltage RF by adjusting the offset of the amplifier included therein.

The turn-on driving voltage Von may be substantially equal to or lower than the driving high voltage VCC. Considering the offset of the amplifier embedded in the gate driver, the turn-on driving voltage Von may be slightly lower than the driving high voltage VCC.

The driving apparatus may reduce the power loss in the GaN device due to the negative current through this driving method. This can improve the overall efficiency of a switching regulator and a power processing circuit employing the GaN device, and also minimize heat generation in the GaN device.

Meanwhile, the driving apparatus illustrated in FIG. 8 may also include the technical contents described with reference to FIGS. 3 to 5.

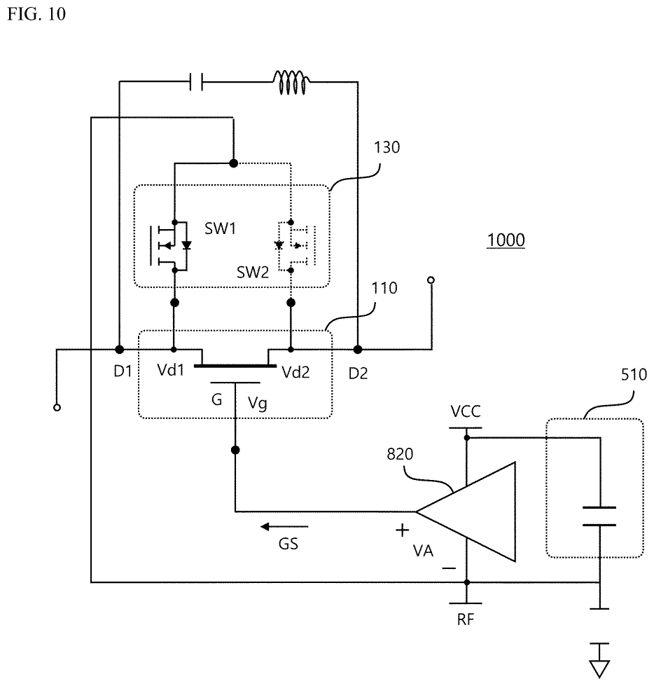

FIG. 10 is a configuration diagram of a bi-directional voltage blocking circuit to which the driving apparatus of FIG. 8 is applied.

Referring to FIG. 10, the bi-directional voltage blocking circuit 1000 may include a GaN device 110, a gate driver 820, and a voltage selector 130. Here, the gate driver 820 and the voltage selector 130 may be the driving apparatus for the GaN device 110.

A first drain terminal D1, a second drain terminal D2, and a gate terminal G may be formed in the GaN device 110. Current may flow from the first drain terminal D1 to the second drain terminal D2 or from the second drain terminal D2 to the first drain terminal D1.

In the GaN device 110, when the gate-first drain voltage, which is the voltage between the gate G and the first drain D1, is higher than the threshold voltage Vth, or when the gate-second drain voltage, which is the voltage between the gate G and the second drain D2, is higher than the threshold voltage Vth, the GaN device 110 may be turned on.

When both the gate-first drain voltage and the gate-second drain voltage in the GaN device 110 are lower than the threshold voltage Vth, the GaN device 110 may be turned off. Since no parasitic diode is formed in the GaN device 110 when the GaN device 110 is turned off, impedance between the first drain terminal D1 and the second drain terminal D2 of the GaN device 110 may become high impedance Hi-Z. Here, the high impedance Hi-Z may vary depending on an application to which the GaN device 110 is applied or the size of the GaN device 110, but may be an impedance value of approximately 1 MΩ or more. In this way, a state in which the impedance between the first drain terminal D1 and the second drain terminal D2 becomes the high impedance Hi-Z may be said to be a state in which the bi-directional voltage is blocked.

In order for the GaN device 110 to be a state of blocking the bi-directional voltage, both the gate-first drain voltage and the gate-second drain voltage should be lower than the threshold voltage Vth. To this end, one embodiment may check the first drain voltage and the second drain voltage. Further, one embodiment may determine the gate voltage Vg using a lower one between the voltages at the first drain terminal and the second drain terminal. For example, when the first drain voltage is lower than the second drain voltage, and the gate-first drain voltage becomes lower than the threshold voltage Vth through the control of the gate voltage, the gate-second drain voltage also becomes lower than the threshold voltage Vth.

The gate driver 820 may supply a driving voltage GS to the gate terminal G of the GaN device 110. At this time, the gate driver 820 may receive the lower one between the voltages at the first drain terminal D1 and the second drain terminal D2 as the reference voltage RF. The gate driver 820 may generate, as a turn-off driving, voltage a driving voltage GS that is higher than the reference voltage RF by a predetermined voltage VA, and then supply the turn-off driving voltage to the gate terminal G. When this turn-off driving voltage is supplied, the GaN device 110 may be turned off.

The gate driver 820 may receive driving power from the charge pump 510. The charge pump 510 may apply a low voltage and a high voltage to the gate driver 820. At this time, the low voltage may be the same as the reference voltage RF of the gate driver 820, and the high voltage may become the driving high voltage VCC of the gate driver 820.

The first drain terminal D1 or the second drain terminal D2 of the GaN device 110 may be in a floating state without being connected to the ground, and the charge pump 510 capable of floating the low voltage may be used to supply driving power to the GaN device 110 in the floating state.

The low voltage of the charge pump 510 may float without being connected to the ground. At this time, if a reference for the low voltage is not properly provided, a voltage difference between the driving voltage GS supplied to the gate terminal G and the first drain terminal D1 or the second drain terminal D2 may become unstable, so that the GaN device 110 may be destroyed. Thus, the reference voltage RF of the gate driver 820 may be used as the low voltage of the charge pump 510.

The voltage selector 130 may include a first switch SW1 disposed between the first drain terminal D1 and the reference terminal of the gate driver, and a second switch SW2 disposed between the second drain terminal D2 and the reference terminal of the gate driver.

The voltage selector 130 may turn on one of the first switch SW1 and the second switch SW2 and apply a lower one between the voltages at the first drain terminal D1 and the second drain terminal D2 as the reference voltage RF of the gate driver. As one example, when the voltage of the first drain terminal D1 is lower than the voltage of the second drain terminal D2, the voltage selector 130 may turn on the first switch SW1 and turn off the second switch SW2 so that the voltage of the first drain terminal D1 is applied as the reference voltage RF. As another example, when the voltage of the second drain terminal D2 is lower than the voltage of the first drain terminal D1, the voltage selector 130 may turn on the second switch SW2 and turn off the first switch SW1 so that the voltage of the second drain terminal D2 is applied as the reference voltage RF.

When the GaN device 110 is turned on, the voltage of the first drain terminal D1 and the voltage of the second drain terminal D2 may become substantially equal. Therefore, the voltage selector 130 may apply, as the reference voltage RF, the voltage of the terminal having a lower average voltage level during a predetermined period of time, for example, a switching cycle.

The first switch SW1 and the second switch SW2 each may be a power semiconductor including a parasitic diode. For example, the first switch SW1 and the second switch SW2 each may be a MOSFET. The first switch SW1 and the second switch SW2 each may include a parasitic diode formed between a drain and a source.

The anode electrode of the parasitic diode embedded in each of the first switch SW1 and the second switch SW2 may be connected to the reference terminal of the gate driver, while the cathode electrode of the parasitic diode may be connected to the first drain terminal D1 or the second drain terminal D2. As one example, the anode electrode of the parasitic diode embedded in the first switch SW1 may be connected to the reference terminal of the gate driver, and the cathode electrode may be connected to the first drain terminal D1. As another example, the anode electrode of the parasitic diode embedded in the second switch SW2 may be connected to the reference terminal of the gate driver, and the cathode electrode may be connected to the second drain terminal D2.

A forward voltage Vf of the parasitic diode embedded in each of the first switch SW1 and the second switch SW2 may be lower than a gate-drain threshold voltage Vth of the GaN device 110. For example, the forward voltage Vf of the parasitic diode embedded in each of the first switch SW1 and the second switch SW2 may be 0.5V, while the gate-drain threshold voltage Vth of the GaN device 110 may be 1V.

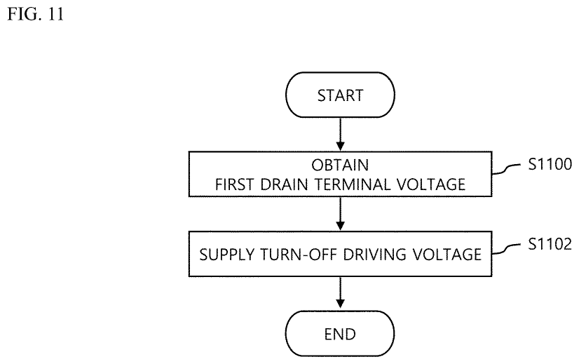

FIG. 11 is a flowchart of a driving method for the driving apparatus shown in FIG. 10.

Referring to FIG. 11, the driving apparatus may obtain the voltage of the first drain terminal, in which an average voltage is formed lower than that of the second drain terminal in the GaN device, in step S1100.

The driving apparatus may supply, to the gate terminal of the GaN device, a turn-off driving voltage that is higher than the voltage of the first drain terminal and lower than a voltage obtained by adding the threshold voltage of the GaN device to the voltage of the first drain terminal, in step S1102.

In a circuit to which such a driving apparatus is applied, when the turn-off driving voltage is supplied to the gate terminal, the current of the inductor connected to the GaN device may flow from the first drain terminal to the second drain terminal. This state is also referred to as a negative current.

The turn-off driving voltage may be supplied to the gate terminal of the GaN device through the gate driver, and the voltage of the first drain terminal may be used as the reference voltage of the gate driver. Further, the gate driver may be supplied with driving power through the charge pump, and the reference voltage may be commonly used by the gate driver and the charge pump.

Meanwhile, in the driving apparatus, a switch may be disposed between the first drain terminal and the gate driver, the switch may incorporate a parasitic diode, the anode electrode of the parasitic diode may be connected to the gate driver, and the cathode electrode of the parasitic diode may be connected to the first drain terminal.

As described above, according to this embodiment, it is possible to provide a bi-directional voltage blocking technology that can reduce the size of a system and lower material costs. Further, according to this embodiment, it is possible to implement a bi-directional voltage blocking function by using a GaN device in which a parasitic diode is not formed. Furthermore, according to this embodiment, it is possible to drive the GaN device while minimizing power loss in the GaN device.

As described above, the terms “include,” “comprise,” or “have,” unless otherwise specifically stated to the contrary, specify the presence of the corresponding component, and therefore should be interpreted not as excluding other components but as further including other components. Unless otherwise defined, all terms including technical and scientific terms have the same meaning as commonly understood by one of ordinary skill in the art to which the present disclosure belongs. It will be further understood that terms used herein should be interpreted as having a meaning that is consistent with their meaning in the context of this specification and the relevant art and will not be interpreted in an idealized or overly formal sense unless expressly so defined herein.

The above description is merely illustrative of the technical idea of the present disclosure, and those skilled in the art to which the present disclosure pertains will be able to make various modifications and changes without departing from the essential characteristics of the present disclosure. Therefore, embodiments disclosed herein are not intended to limit but to illustrate the technical idea of the present disclosure, and the scope of the technical idea of the present disclosure is not limited by these embodiments. The protection scope of the present disclosure should be interpreted according to the following claims, and all technical ideas within the equivalent scope thereof should be construed as being included in the scope of rights of the present disclosure.

1. A driving apparatus for a gallium nitride (GaN) device, the driving apparatus comprising:
a gate driver for supplying a gate terminal of the GaN device with a driving voltage generated by using a reference voltage and a driving high voltage; and
a voltage selector for applying, as the reference voltage of the gate driver, a lower one between voltages at a first drain terminal and a second drain terminal of the GaN device.

2. The driving apparatus of claim 1, wherein the gate driver is supplied with driving power through a charge pump, and the reference voltage is used as a low voltage of the charge pump.

3. The driving apparatus of claim 1, wherein the voltage selector comprises a first switch disposed between the first drain terminal and the gate driver and a second switch disposed between the second drain terminal and the gate driver, and turns on one of the first switch and the second switch to apply the lower one between the voltages as the reference voltage of the gate driver.

4. The driving apparatus of claim 3, wherein the first switch and the second switch each comprises a parasitic diode formed between a drain and a source.

5. The driving apparatus of claim 4, wherein an anode electrode of the parasitic diode is connected to a reference terminal of the gate driver, and a cathode electrode of the parasitic diode is connected to the first drain terminal or the second drain terminal.

6. The driving apparatus of claim 4, wherein a forward voltage of the parasitic diode is lower than a threshold voltage of a gate-drain of the GaN device.

7. A driving method for a gallium nitride (GaN) device, the driving method comprising:
applying a lower one between the voltages at a first drain terminal and a second drain terminal of the GaN device, as a reference voltage of a gate driver; and
supplying a turn-off driving voltage having a voltage level corresponding to the reference voltage to a gate terminal of the GaN device, thereby making impedance between the first drain terminal and the second drain terminal of the GaN device high impedance (Hi-Z).

8. The driving method of claim 7, wherein, in the applying the lower voltage as the reference voltage of the gate driver, the drain terminal having a lower voltage between the first drain terminal and the second drain terminal is connected to the reference terminal of the gate driver.

9. The driving method of claim 8, wherein a first switch is disposed between the first drain terminal and the reference terminal, a second switch is disposed between the second drain terminal and the reference terminal, and one of the first switch and the second switch is turned on to connect the drain terminal having a lower voltage to the reference terminal.

10. The driving method of claim 9, wherein: the gate driver is supplied with driving power through a charge pump, and the first switch and the second switch each comprises a parasitic diode formed between a drain and a source.

11. A driving method for a gallium nitride (GaN) device, the driving method comprising:
obtaining a voltage of a first drain terminal, in which an average voltage in the GaN device is formed lower than that of a second drain terminal; and
supplying, to a gate terminal of the GaN device, a turn-off driving voltage that is higher than the voltage of the first drain terminal and lower than a voltage obtained by adding a threshold voltage of the GaN device to the voltage of the first drain terminal.

12. The driving method of claim 11, wherein when the turn-off driving voltage is supplied to the gate terminal, current of an inductor connected to the GaN device flows from the first drain terminal to the second drain terminal.

13. The driving method of claim 11, wherein: the turn-off driving voltage is supplied through a gate driver to the gate terminal of the GaN device, and the voltage of the first drain terminal is used as a reference voltage of the gate driver.

14. The driving method of claim 13, wherein: the gate driver is supplied with driving power through a charge pump, and the reference voltage is commonly used by the gate driver and the charge pump.

15. The driving method of claim 13, wherein a switch is disposed between the first drain terminal and the gate driver, the switch comprises a parasitic diode therein, an anode electrode of the parasitic diode is connected to the gate driver, and a cathode electrode of the parasitic diode is connected to the first drain terminal.
